(19) United States
(12) Patent Application Publication
(10) Pub. No.: US 2009/0129012 A1
(43) Pub. Date: May 21, 2009

(54) METHOD AND APPARATUS FOR HEAT TRANSFER

(76) Inventors: Anton Legen, Munich (DE); Lutz Morgenroth, Munich (DE); Steve Wood, Munich (DE)

Correspondence Address: PATTERSON & SHERIDAN, LLP;Gero McClellan / Qimonda, 3040 POST OAK BLVD.,, SUITE 1500, HOUSTON, TX, 77056, US

(21) Appl. No.: 11/944,374

(22) Filed: Nov. 21, 2007

(51) Int. Cl. H05K 7/20

(52) U.S. Cl. 361/690; 361/707

(57) ABSTRACT

A heat transfer apparatus for a memory module with a heat spreader that includes a channel being attachable on top of the memory module, and further includes attachment parts that are in thermal communication with the channel to engage with the heat spreader.

### BACKGROUND OF THE INVENTION

1. Field of the Invention

The invention relates to a heat transfer apparatus for a memory module.

2. Description of the Related Art

Semiconductor devices continue to shrink while the operational frequencies of the devices constantly increase. The combination of reduced size and higher frequencies results in a higher power density that increases the temperature of the devices. Cooling solutions are used to prevent overheating of the devices, which may for example lead to malfunction, reduced functionality or even destruction of the devices.

Cooling solutions are employed in many technical fields including, for example, consumer electronics (e.g. TV sets or HiFi components), computer (e.g. for processors, memories, chip sets or hard disks), or industrial electronics (e.g. power amplifier).

The afore said applies as well to memory modules for computer. For example, memory modules may be DIMMs (Dual Inline Memory Module), registered DIMMs, fully buffered DIMMS, SO-DIMMs or any other type of memory module.

### BRIEF DESCRIPTION OF THE DRAWINGS

The accompanying drawings are included to provide a further understanding of embodiments and are incorporated in and constitute part of the specification. The drawings illustrate embodiments and together with the description serve to explain principles of embodiments. Other embodiments and many of the intended advantages of embodiments will be readily appreciated as they become better understood by reference to the following detailed description. The elements of the drawings are not necessarily to scale relative to each other. Like reference numerals designate corresponding similar parts.

FIG. 1 illustrates a perspective view of a memory module equipped with a heat transfer apparatus in accordance to an embodiment of the invention.

FIG. 2 illustrates a front view of the heat transfer apparatus illustrated in FIG. 1 according to an embodiment of the invention.

FIG. 3 illustrates a perspective view of a memory module equipped with the heat transfer apparatus in accordance to an embodiment of the invention.

FIG. 4 illustrates a front view of the heat transfer apparatus illustrated in FIG. 3 according to an embodiment of the invention.

### DETAILED DESCRIPTION OF THE PREFERRED EMBODIMENT

In the following detailed description reference is made to the accompanying drawings which form part thereof and in which is shown by way of illustration specific embodiments in which the invention may be practiced. In this regard directional terminology such as “top”, “bottom”, “front”, “back”, “leading”, “trailing”, etc. is used with reference to the orientation of the Figures being described. Because components of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description therefore is not to be taken in a limiting sense and the scope of the present invention is defined by the appended claims.

It is to be understood that the features of the various examples described herein may be combined with each other, unless specifically noted otherwise.

While the invention is described with respect to memory modules, it is not limited thereto. The invention may be used with any kind of module which comprises electronic components producing heat. For example, these modules may be processor modules, daughter cards, or power modules.

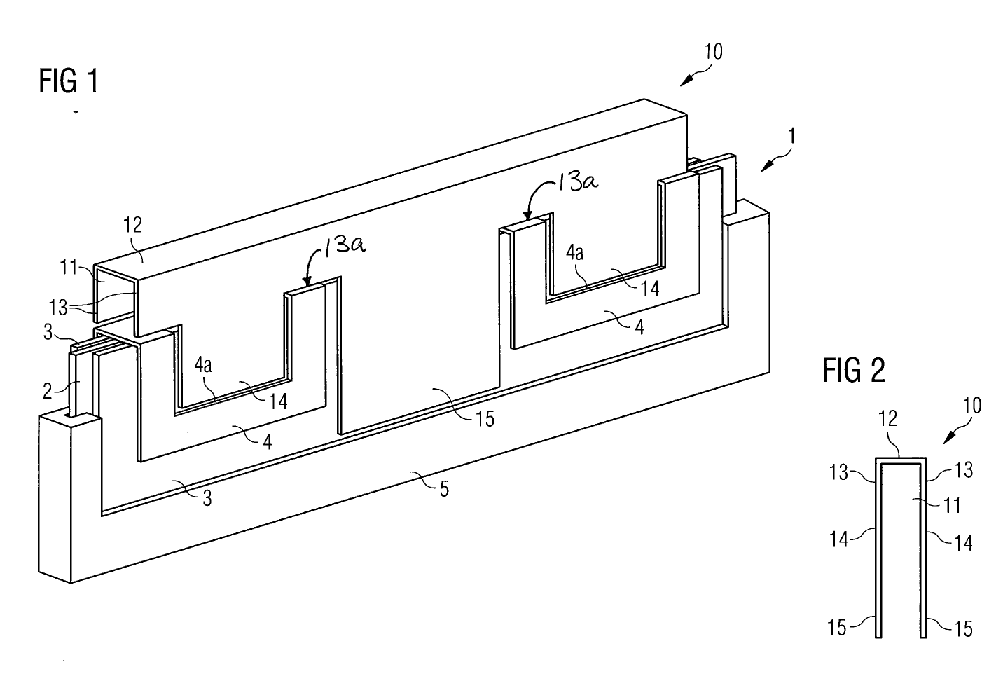

FIG. 1 shows a memory module 1 having a circuit board 2 including memory chips (not illustrated) according to one embodiment. The memory chips may be arranged on one or both sides of the circuit board 2. The memory chips may be covered by a heat spreader 3 that may consist of aluminum. The heat spreader 3 may be arranged on one or both sides of the circuit board 2. In the illustrated embodiment of FIG. 1, two heat spreaders are shown, one on either side of the circuit board 2. In one embodiment, the heat spreaders 3 may be connected to the circuit board 2 by a pair of clips 4 that may include springy metal to press the heat spreaders 3 against the circuit board 2. In another embodiment, the heat spreaders 3 may be fixed by screws, rivets or may consist of one piece.

The illustrated memory module 1 may be inserted into a memory socket 5 that may be arranged on a motherboard of a computer system. A motherboard usually comprises two or more memory sockets 5 that are arranged in parallel so that inserted memory modules 1 are aligned in parallel relatively close to each other.

The memory module 1, as illustrated in FIG. 1, is equipped with an embodiment of the heat transfer apparatus 10. The heat transfer apparatus 10 may include a channel 11 that is arranged on top of the memory module 1. The channel 11 may be defined by a top wall 12 and two sidewalls 13. The two sidewalls 13 may be parallel to one another and may be connected by the top wall 12. The bottom side of the channel 11 may be defined by the upper part of the memory module 1.

Reference is made to the top or the sides of the memory module. In this description, top of the memory module means opposite to connectors of the memory module that engage the socket 5. The sides of the memory module are the surfaces between the top and the connectors.

The terms top and sides are used to facilitate the understanding of the description. If a memory module is mounted horizontally (e.g. in a daughter board), or inclined (e.g. in a blade server) the heat transfer apparatus might not be arranged on top of the memory module as seen from a system point of view.

As seen from a memory module view the heat transfer apparatus is on top of the memory module. The terms used herein refer to the memory module view.

The heat transfer apparatus 10 may be secured to the memory module 1 by attachment parts 14. In the illustrated embodiment of FIG. 1, four attachment parts 14 are provided, two on each side of the memory module 1. The attachment parts 14 may engage the heat spreaders 3 so that the heat transfer apparatus 10 is fixed to the memory module 1. The attachment parts 14 may be resilient and be biased toward each other to define a spacing less than the outer diameter between the heat spreaders 3. In this way, the heat transfer apparatus 10 may be attached to the memory module 1 by clipping it on the heat spreader 3 via the attachment parts 14. The biasing of the attachment parts 14 toward each other ensures good contact between the attachment parts 14 and the heat spreader 3 as well as effects a gripping action, thereby securing the heat transfer apparatus 10 to the heat spreaders 3 and memory module 1. In another embodiment, the attachment parts 14 may be adhesively fixed to the heat spreader 3. In another embodiment, the sidewalls 11 of the heat transfer apparatus 10 may be engaged by clipping the sidewalls 11 on the heat spreader.

The heat transfer apparatus 10 further comprises a contact portion 15, which contacts the heat spreader 3 in order to transfer heat from the heat spreader 3 and thereby from the memory module 1 to the heat transfer apparatus 10. To facilitate heat transfer from the heat spreader 3 to the heat transfer apparatus 10, thermal interface material, such as thermal grease, may be used between the heat spreader 3 and the contact portion 15. The contact portion 15 may be resilient or bent inwards (i.e. towards the heat spreader 3) for good contact between the heat spreader 3 and the contact portion 15.

In one embodiment, the heat transfer apparatus 10 may be one piece, for example integrally formed from a piece of aluminum or copper. In another embodiment, the heat transfer apparatus 10 may comprise metal, graphite, or a combination of both. The whole heat transfer apparatus 10 may be resilient, not only the attachment parts 14 or the contact portion 15. The attachment parts 14 and the contact portions 15 extend from the sidewalls 13. The attachment parts 14 and the contact portions 15 may be part of the sidewalls 13, while the parts of the sidewalls 13 that are defining the channel 11 are stretching continuously and the attachment parts 14 and the contact portions 15 are divided by recesses 13a in the sidewalls 13. In one embodiment, the recesses in the sidewalls 13 may be adapted to fit over a protrusion, for example the clips 4, of the heat spreader 3.

As can be seen from the front view illustrated in FIG. 2 the sidewalls 13, the attachment parts 14 and the contact portions 15 may be arranged in the same planes according to one embodiment. The sidewalls 13 may be perpendicular to the top wall 12 so that the heat transfer apparatus is generally U-shaped. The top wall may have the form of a cylinder or a prism.

The orientation of the heat transfer apparatus 10 is labeled as a front view. This is with reference to the direction of a cooling medium which flows parallel to the length of the channel 11. One could designate FIG. 2 as a side view as well if the reference would be the memory module 1. A front side of a memory module is usually one of the main surfaces.

Referring back to FIG. 1, the heat transfer apparatus 10 may be adapted to fit into the clips 4 of the heat spreader 3. The attachment parts 14 may be sized such that they fit into recesses 4a of the clips 4. The width of the contact portion 15 may be chosen such that the contact portion 15 just fits in between the pair of clips 4. The length or height of the contact portion 15 may be such that it ends above the memory slot 5. In one embodiment, the contact portion 15 may be constructed to maximize the contact area between the contact portion 15 and the heat spreader 3. In another embodiment, the contact portion 15 may be designed to contact a single hot spot of the memory module 1 including, for example, a register or a buffer chip. In this case, the contact portion 15 may be relatively small but directed to a certain point of the heat spreader 3.

As illustrated in FIG. 1, the length of the heat transfer apparatus 10 may be such that it stops at the outer edges of the clips 4. The length of the channel 11 may be chosen such that the top wall 12 and the sidewalls 13 extend to one or both ends of the memory module 1 or above the memory module 1. This decision can depend on features of the computer system into which the memory module 1 equipped with the heat transfer apparatus 10 is inserted. These features may include velocity and direction of an air stream, which is provided in the computer system or the location and quantity of memory modules.

As an example of operation, the electrical components of the memory module 1 may heat up during operation. The heat may spread into the heat spreaders 3 and is transferred by the attachment parts 14 and the contact portion 15 to the sidewalls 13. The contact portions 15 are optional. Depending on the circumstances, only one contact portion 15 or no contact portion is needed to transport the heat away from the heat spreader 3 towards the sidewalls 13.

A cooling medium, usually air, may be streaming along the memory module 1, thereby taking away heat from the heat spreader 3 at the sides of the memory module 1. Additional cooling may be achieved by the channel 11. Part of the surrounding air stream flows through the channel 11, thereby taking away heat from the sidewalls 13, the top wall 12, and the top of the memory module 1. Another part of the air stream flowing along the outer boundaries of the channel 11 (i.e. the top wall 13 and the sidewalls 13) takes away heat as well.

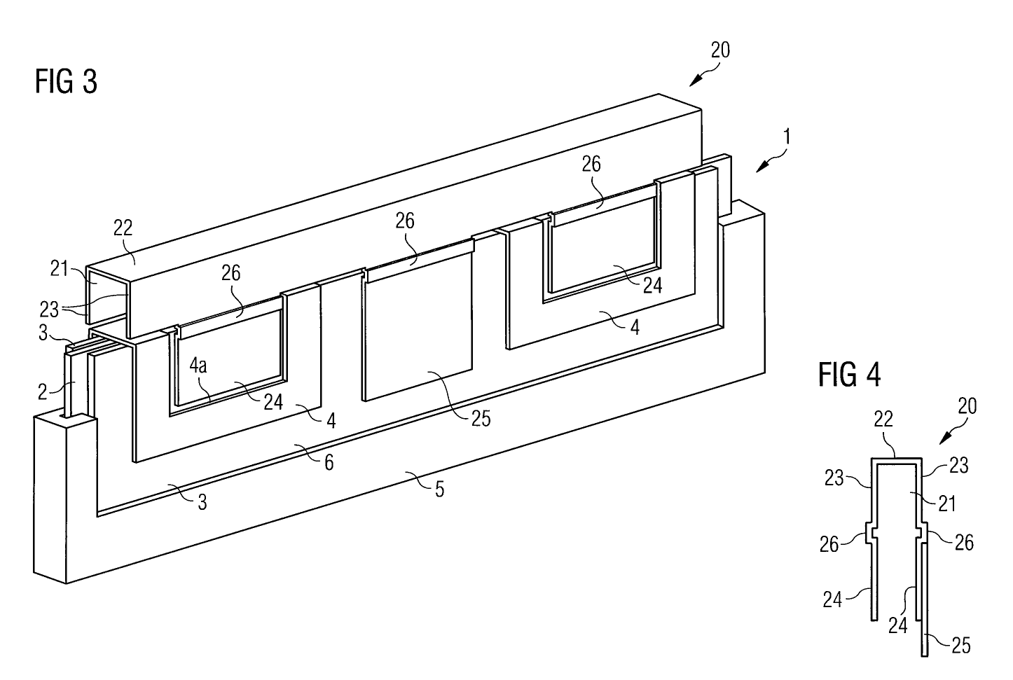

Another embodiment of the invention is illustrated in FIGS. 3 and 4. Here, the memory module 1 may include a circuit board 2 on which memory chips (not illustrated) are disposed. The memory chips may be covered by heat spreaders 6. The heat spreaders 6 may be attached to the circuit board 2 by a pair of clips 4. The memory module 1 may be inserted into a memory socket 5. The heat spreader 6 may comprise a reinforced upper edge (not illustrated).

The heat transfer apparatus 20 may include a channel 21 defined by an upper wall 22 and two sidewalls 23. In an attached state of the heat transfer apparatus 20 the channel 21 may be arranged above the memory module 1. The heat transfer apparatus 20 may be attached to the heat spreader 6 by attachment parts 24, which may be arranged on each side of the memory module 1. In the illustrative embodiment shown in FIG. 3, the heat transfer apparatus 20 includes four attachment parts 24, with two attachment parts arranged on either side of the memory module 1.

The memory module 1 may comprise a hot spot (e.g. a logic chip including a register or a buffer chip). The heat transfer apparatus 20 may include a contact portion 25 to establish thermal communication to the hot spot of the memory module 1. The contact portion 25 may be arranged at one side of the heat transfer apparatus and may contact a certain part of the heat spreader 6 above the hot spot.

In one embodiment, it may be possible as well to provide multiple contact portions. In another embodiment, central contact portions adapted to fit in between the pair of clips 4 may be provided. In case of a memory module without clips, the attachment parts and the contact portions may be integrated into one portion. This particular portion may be an extension of the sidewall 23 and may span the whole length of the heat transfer apparatus. This particular portion may be provided at both sides of the heat transfer apparatus.

In one embodiment, the attachment parts 24 and the contact portion 25 may each comprise an elongated recess 26 which is adapted to fit over the reinforced edge of the heat spreader 6.

As seen in FIG. 4, the contact portion 25 may be located further away from the channel 21 than the attachment parts 24 according to one embodiment. This example of the heat transfer apparatus 20 is adapted to a heat spreader 6 having a surface with different heights, for example, adapted to a buffer chip.

The above description refers several times to an assembled unit (i.e. a memory unit with attached heat transfer apparatus). Those skilled in the art will appreciate that the invention may not only encompass the assembled unit but the discrete add-on as well. For example, the memory unit including a heat spreader may be a base unit while the heat transfer apparatus may be designed as an add-on to the heat spreader of the memory module.

The illustrated examples may be combined or certain features of one example may be implemented in a different example. The elongated recess 26 of the example shown in FIGS. 3 and 4 may be implemented in the example shown in FIGS. 1 and 2.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore it is intended that this invention be limited only by the claims and the equivalents thereof.

What is claimed is:

1. A heat transfer apparatus for a memory module having a heat spreader, the heat transfer apparatus comprising:
a body that forms a channel; wherein the body is attachable on top of the memory module; and
attachment parts in thermal communication with the channel; wherein the attachment parts engage the heat spreader.

2. The heat transfer apparatus according to claim 1, wherein the channel is defined by a top wall and two sidewalls and wherein the attachment parts extend from the sidewalls.

3. The heat transfer apparatus according to claim 1, wherein the attachment parts are resilient.

4. The heat transfer apparatus according to claim 1, wherein the attachment parts are engaged by clipping the attachment parts on the heat spreader.

5. The heat transfer apparatus according to claim 1, wherein the attachment parts are engaged by adhesively fixing the attachment parts to the heat spreader.

6. The heat transfer apparatus according to claim 1, wherein the attachment parts fit in recesses of clips of the heat spreader.

7. The heat transfer apparatus according to claim 1, further comprising a contact portion to contact the heat spreader.

8. The heat transfer apparatus according to claim 1, wherein the heat transfer apparatus comprises metal, graphite, or a combination of both.

9. A heat transfer apparatus for a memory module having a heat spreader, the heat transfer apparatus comprising:
a top wall; and
two sidewalls connected by the top wall;
wherein the two sidewalls are engageable to the heat spreader, whereby the top wall is positioned above the memory module and whereby a channel is formed between the top wall, the two sidewalls and the memory module.

10. The heat transfer apparatus according to claim 9, wherein the sidewalls have a lateral separation less than an outer diameter defined by the respective surfaces of the heat spreader on which the respective sidewalls are disposed.

11. The heat transfer apparatus according to claim 9, wherein one of the sidewalls comprises attachment parts, wherein the attachment parts engage the heat spreader.

12. The heat transfer apparatus according to claim 9, wherein one of the sidewalls comprises a contact portion, wherein the contact portion contacts the heat spreader at a region predetermined to be a hottest spot on the heat spreader.

13. The heat transfer apparatus according to claim 9, wherein the sidewalls are engaged by clipping the sidewalls on the heat spreader.

14. The heat transfer apparatus according to claim 9, wherein the sidewalls are engaged by adhesively fixing the sidewalls to the heat spreader.

15. The heat transfer apparatus according to claim 11, wherein the attachment parts fit in recesses of clips of the heat spreader.

16. The heat transfer apparatus according to claim 9, wherein the sidewalls comprise a recess, wherein the recess is adapted to fit over a protrusion of the heat spreader.

17. A memory module comprising:
a circuit board having memory chips;
a heat spreader covering the memory chips; and
a heat transfer apparatus attached to the heat spreader;
wherein the heat transfer apparatus comprises:
a body forming a channel arranged on top of the memory module; and
attachment parts in thermal communication with the body and in contact with the heat spreader.

18. The memory module according to claim 17, wherein the heat transfer apparatus comprises a contact portion, wherein the contact portion contacts the heat spreader.

19. The memory module according to claim 17, wherein the attachment parts are clipped on the heat spreader.

20. The memory module according to claim 17, wherein the attachment parts are engaged by adhesively fixing the attachment parts to the heat spreader.

21. A heat transfer apparatus for a memory module having a heat spreader comprising:
means for guiding an air flow attachable on top of the memory module; and
means for attaching the heat transfer apparatus to the heat spreader being in thermal communication with the means for guiding.

22. A method for improving cooling of a memory module having a heat spreader cooled by an air flow, comprising:
guiding the air flow through a channel formed in a body above the memory module; and
transferring heat from the memory module to the top of the memory module.
